(19) United States
(12) Patent Application Publication
(10) Pub. No.: US 2025/0069961 A1
(43) Pub. Date: Feb. 27, 2025

(54) SEMICONDUCTOR WAFER AND OPERATING METHOD OF TEST CIRCUIT OF SEMICONDUCTOR WAFER

(71) Applicant: Samsung Electronics Co., Ltd., Suwon-si (KR)

(72) Inventors: Jinyong Choi, Suwon-si (KR); Sooyeol Yang, Suwon-si (KR); Jaeeun Lee, Suwon-si (KR); Hyuckjoon Kwon, Suwon-si (KR); Jinwon Choi, Suwon-si (KR); Takuya Futatsuyama, Suwon-si (KR)

(21) Appl. No.: 18/800,813

(22) Filed: Aug. 12, 2024

(30) Foreign Application Priority Data
Aug. 23, 2023 (KR) 10-2023-0110761

(51) Int. Cl. H01L 21/66; G01R 31/28

(52) U.S. Cl. CPC H01L 22/32; G01R 31/2831; H01L 22/14

(57) ABSTRACT

A semiconductor multi-layer structure includes a first semiconductor wafer including a plurality of first pads, a second semiconductor wafer including a plurality of second pads combined with the plurality of first pads, and a test circuit configured to apply a first voltage to a reference combination portion in which a preset first reference pad among the plurality of first pads is combined with a preset second reference pad among the plurality of second pads and apply a second voltage to a comparison combination portion in which at least one first pad among the plurality of first pads is combined with at least one second pad among the plurality of second pads, wherein the test circuit compares a voltage distributed based on a resistance ratio of the reference combination portion to the comparison combination portion with a preset reference voltage to determine whether the at least one first pad is aligned with the at least one second pad.

### CROSS-REFERENCE TO RELATED APPLICATION

This application is based on and claims priority under 35 U.S.C. § 119 to Korean Patent Application No. 10-2023-0110761, filed on Aug. 23, 2023, in the Korean Intellectual Property Office, the disclosure of which is incorporated by reference herein in its entirety.

### BACKGROUND

Embodiments relate to a semiconductor wafer and an operating method of a test circuit of the semiconductor wafer, and more particularly, to a semiconductor wafer and an operating method of a test circuit of a semiconductor wafer that determine whether the semiconductor wafer including a plurality of layers is misaligned.

With improved semiconductor manufacturing technology, various processes of manufacturing semiconductor devices are being developed. One of the various processes includes combining two or more semiconductor dies to manufacture one semiconductor device or combining two or more semiconductor wafers to manufacture a plurality of semiconductor devices.

When combining two or more semiconductor dies or semiconductor wafers, aligning the semiconductor dies or semiconductor wafers with one another may be an important factor in determining yield. Also, recently developed memory devices may operate according to various specifications, and non-volatile memory devices may each have a three-dimensional structure. In addition, non-volatile memory devices are manufactured on a wafer basis in a manufacturing process, and respective wafers have to be aligned with each other because the wafers are stacked in a three-dimensional structure.

### SUMMARY

As described above, when manufacturing one semiconductor device by combining two or more semiconductor dies or manufacturing a plurality of semiconductor devices by combining two or more semiconductor wafers, a device and method of determining whether a plurality of semiconductor wafers are aligned with each other are required. However, there is a problem in that whether the semiconductor wafers are aligned with each other is not accurately determined.

According to an aspect of the inventive concept, a semiconductor multi-layer structure includes a first semiconductor wafer including a plurality of first pads, a second semiconductor wafer including a plurality of second pads combined with the plurality of first pads, and a test circuit configured to apply a first voltage to a reference combination portion in which a preset first reference pad among the plurality of first pads is combined with a preset second reference pad among the plurality of second pads and apply a second voltage to a comparison combination portion in which at least one first pad among the plurality of first pads is combined with at least one second pad among the plurality of second pads, wherein the test circuit compares a voltage distributed based on a resistance ratio of the reference combination portion to the comparison combination portion with a preset reference voltage to determine whether the at least one first pad is aligned with the at least one second pad.

According to another aspect of the inventive concept, a semiconductor multi-layer structure includes a first semiconductor wafer including a plurality of first pads, a second semiconductor wafer including a second plurality of second pads combined with the plurality of first pads, and a scanner configured to perform electron beam scanning of a reference combination portion in which a preset first reference pad among the plurality of first pads is combined with a preset second reference pad among the plurality of second pads and a comparison combination portion in which at least one first pad among the plurality of first pads is combined with at least one second pad among the plurality of second pads, wherein the scanner determines whether the at least one first pad is aligned with the at least one second pad based on the amount of electrons reflected from the reference combination portion and the comparison combination portion during the electron beam scanning.

According to another aspect of the inventive concept, an operating method of a test circuit for determining whether a semiconductor multi-layer structure including a three-dimensional memory device is aligned includes applying a first voltage to a reference combination portion in which a preset first reference pad among a plurality of first pads included in a first wafer is combined with a preset second reference pad among a plurality of second pads included in a first wafer, applying a second voltage to a comparison combination portion in which at least one first pad among the plurality of first pads is combined with at least one second pad among the plurality of second pads, and determining whether the at least one first pad is aligned with the at least one second pad by comparing a voltage distributed based on a resistance ratio of the reference combination portion to the comparison combination portion with a preset reference voltage.

### BRIEF DESCRIPTION OF THE DRAWINGS

Embodiments of the inventive concept will be more clearly understood from the following detailed description taken in conjunction with the accompanying drawings in which:

FIG. 1 illustrates a semiconductor wafer according to one embodiment;

FIGS. 2A and 2B are block diagrams of a semiconductor wafer according to one embodiment;

FIG. 3 is a block diagram illustrating a test circuit according to one embodiment;

FIGS. 4A and 4B are diagrams illustrating a process of determining whether a semiconductor wafer is aligned, according to one embodiment;

FIGS. 5 and 6 illustrate a process of determining whether a semiconductor wafer is aligned by using a scanner, according to one embodiment;

FIG. 7 is a flowchart of an operating method of a test circuit according to one embodiment;

FIG. 8 is a flowchart illustrating a method determining an alignment tendency of a first pad and a second pad in the operating method of the test circuit, according to one embodiment; and

FIGS. 9 to 11 are views illustrating a three-dimensional V-NAND structure that may be applied to a memory device, according to one embodiment.

### DETAILED DESCRIPTION OF THE EMBODIMENTS

Hereinafter, preferred embodiments of the inventive concept are described with reference to the attached drawings. Below, details of a configuration and structure are provided to help readers understand the embodiments. Therefore, the embodiments described herein may be changed or modified in various ways without departing from the embodiments.

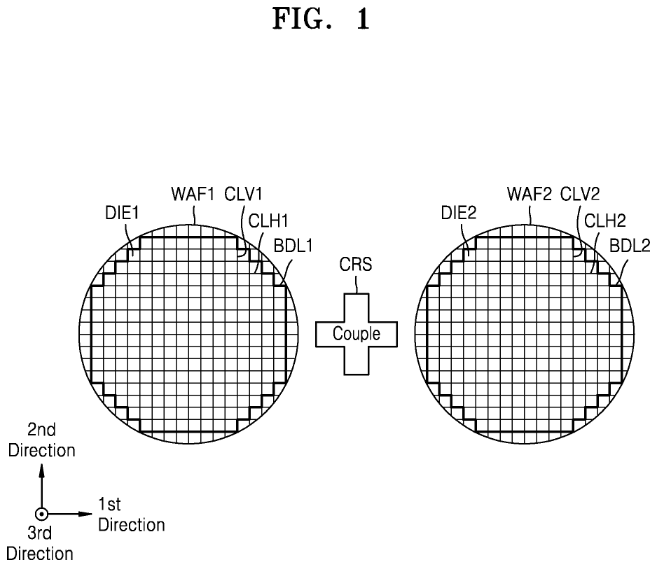

FIG. 1 illustrates a first wafer WAF1 (i.e., a first semiconductor wafer) and a second wafer WAF2 (i.e., a second semiconductor wafer) according to one embodiment.

Referring to FIG. 1, the first wafer WAF1 is combined with the second wafer WAF2, the first wafer WAF1 may include at least one first die DIE1, and the second wafer WAF2 may include at least one second die DIE2. The embodiment of FIG. 1 illustrates an example in which the at least one first die DIE1 is combined with the at least one second die DIE2.

Referring to FIG. 1, in order to combine the first die DIE1 with the second die DIE2, the first die DIE1 may be rotated 180 degrees in a first direction (e.g., a first horizontal direction). Accordingly, a coordinate system of the first die DIE1 and a coordinate system of the second die DIE2 may be displayed separately.

The first die DIE1 may include first pads arranged on an upper surface thereof in a third direction (e.g., a vertical direction). The first pads may be arranged at equal intervals in the first direction and a second direction (e.g., a second horizontal direction perpendicular to the first horizontal direction).

The second die DIE2 may include second pads arranged on an upper surface thereof in the third direction. The second pads may be arranged at equal intervals in the first and second directions.

As illustrated by a cross CRS in FIG. 1, the first wafer WAF1 and the second wafer WAF2 may be coupled/combined to each other to implement a plurality of semiconductor devices (e.g., nonvolatile memory devices). A plurality of semiconductor devices in which the first semiconductor dies DIE1 and the second semiconductor dies DIE2 are coupled may be obtained by coupling the first semiconductor wafer WAF1 and the second semiconductor wafer WAF2 and cutting a result of the coupling, e.g., by cutting the combined product of the first and second semiconductor wafers WAF1 and WAF2. As used herein, the term “semiconductor multi-layer structure” may be used to describe the structure of the combined/coupled first wafer WAF1 and the second wafer WAF.

When the first wafer WAF1 is combined with the second wafer WAF2, the first pads of the first die DIE1 may be combined with the second pads of the second die DIE2. When positions of the first pads and positions of the second pads are accurately aligned (for example, aligned with each other within an allowable error range), the combination of the first wafer WAF1 with the second wafer WAF2 may be successful. When the positions of the first pads and the positions of the second pads are not accurately aligned (for example, aligned outside the allowable error range) with each other, the combination of the first wafer WAF1 with the second wafer WAF2 may fail.

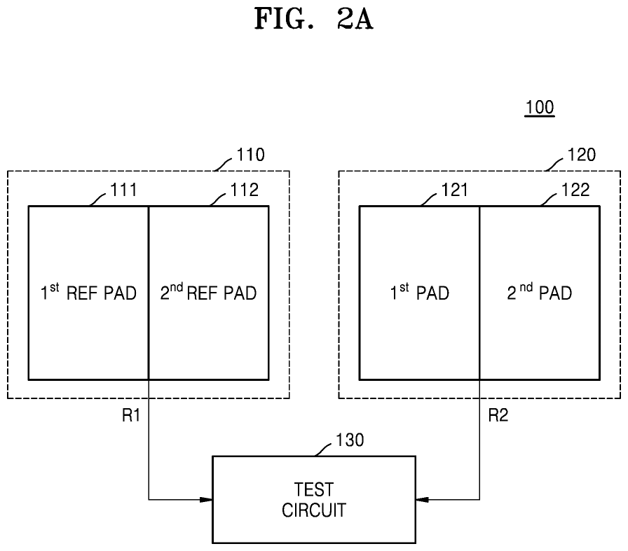

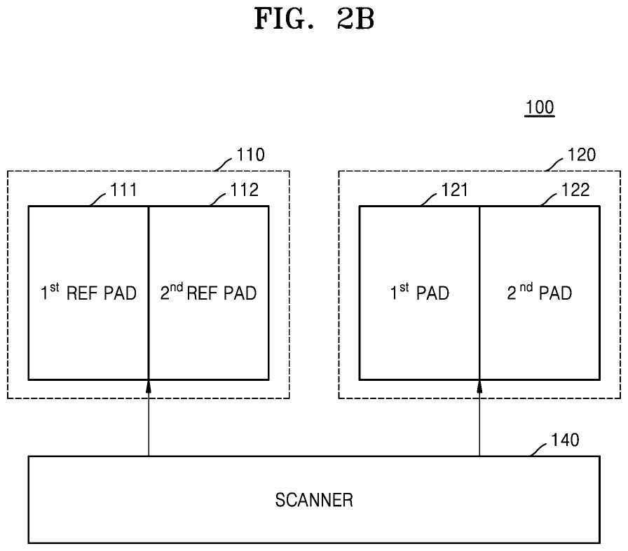

FIGS. 2A and 2B are block diagrams of a semiconductor multi-layer structure 100 according to one embodiment. The semiconductor multi-layer structure 100 in FIG. 2A illustrates an embodiment in which alignment is determined by a test circuit 130, and the semiconductor multi-layer structure 100 in FIG. 2B illustrates an embodiment in which alignment is determined by a scanner 140. For example, the first and/or second semiconductor wafers WAF1 and WAF2 may be implemented with the test circuit 130.

The test circuit 130 according to one embodiment may be located on either the first wafer WAF1 or the second wafer WAF2. For example, the test circuit 130 may be located on the first wafer WAF1. Alternatively, the test circuit 130 may be located on the second wafer WAF2. The scanner 140 according to one embodiment may be located on a different chip or a different wafer, separate from both the first wafer WAF1 and the second wafer WAF2.

Referring to FIG. 2A, the semiconductor multi-layer structure 100 according to one embodiment may include a reference combination portion 110, a comparison combination portion 120, and the test circuit 130.

The reference combination portion 110 according to one embodiment may be a combination portion of a first reference pad 111 and a second reference pad 112. The first reference pad 111 according to one embodiment may be a reference pad selected from a plurality of first pads, and the second reference pad 112 may be a reference pad selected from a plurality of second pads. Also, the plurality of first pads may be on the first wafer WAF1 in FIG. 1 and the plurality of second pads may be on the second wafer WAF2 in FIG. 1. Also, the plurality of first pads and the plurality of second pads may be arranged to have a square matrix structure. For example, the first pads and the second pads may be arranged in a 9×9 structure, a 10×10 structure, or a 12×12 structure but are not limited thereto and may be arranged in a square matrix structure of various sizes.

A first reference pad 111 and a second reference pad 121 of the reference combination portion 110 according to one embodiment may be aligned with each other 100%. A preset voltage may be applied to the reference combination portion 110 according to one embodiment, and the reference combination portion 110 may have a reference resistance value R1. In one embodiment, the voltage applied to the reference combination portion 110 may be referred to as a first voltage. Also, the first voltage may be an external voltage applied from the outside of the semiconductor multi-layer structure 100 or may be an internal voltage applied from the inside of the semiconductor multi-layer structure 100.

The comparison combination portion 120 according to one embodiment may be a combination portion of a first pad 121 randomly selected from a plurality of first pads and a second pad 122 randomly selected from a plurality of second pads. A preset voltage may be applied to the comparison combination portion 120 according to one embodiment, and the comparison combination portion 120 may have a comparison resistance value R2. In one embodiment, the voltage applied to the comparison combination portion 120 may be referred to as a second voltage. Also, the second voltage may be an external voltage applied from the outside of the semiconductor multi-layer structure 100, or may be an internal voltage applied from the inside of the semiconductor multi-layer structure 100.

The test circuit 130 according to one embodiment may compare a voltage distributed based on a resistance ratio of the reference combination portion 110 to the comparison combination portion 120 with a preset reference voltage to determine whether at least one of the first pads and at least one of the second pads are aligned with each other. For example, the test circuit 130 may compare a voltage according to the distribution of the first voltage applied to the reference combination portion 110 and the second voltage applied to the comparison combination portion 120 with a preset reference voltage to determine whether the first pad 121 and the second pad 122 are aligned with each other.

Also, the test circuit 130 may determine the degree of misalignment of the first pad 121 and the second pad 122 of the comparison combination portion 120. According to one embodiment, the test circuit 130 may compare a voltage according to the distribution of the first voltage applied to the reference combination portion 110 and the second voltage applied to the comparison combination portion 120 with a preset reference voltage, and compare the distributed voltage with a preset answer sheet (e.g., a preset or predetermined value(s) that may be stored in memory), thereby determining the degree of alignment of the first pad 121 and the second pad 122 with one another. For example, the test circuit 130 may compare the voltage according to the distribution of the first voltage and the second voltage with the reference voltage of the preset answer sheet, and when misalignment is found, the test circuit 130 may check a change in the voltage according to the distribution of the first and second voltages changed through a change in the reference voltage and compare the voltage with the preset answer sheet, thereby determining the degree of alignment of the first pad 121 and the second pad 122.

Also, the test circuit 130 may determine an alignment tendency of the first pad 121 and the second pad 122 of the comparison combination portion 120. According to one embodiment, the test circuit 130 may repeat a process of comparing the voltage according to the distribution of the first voltage applied to the reference combination portion 110 and the second voltage applied to the comparison combination portion 120 with the preset reference voltage and determining the degree of alignment of the first pad 121 and the second pad 122. For example, the test circuit 130 may determine whether a plurality of pads are aligned with each other and the degree of alignment of the plurality of pads by comparing the voltage according to the distribution of the first voltage applied to the reference combination portion 110 and the second voltage applied to the comparison combination portion 120 with the preset reference voltage for the comparison combination portion 120 including at least one of the plurality of first pads and at least one of the plurality of second pads.

Referring to FIG. 2B, the semiconductor multi-layer structure 100 according to one embodiment may include the reference combination portion 110, the comparison combination portion 120, and the scanner 140.

Descriptions of the reference combination portion 110 and the comparison combination portion 120 are the same as in FIG. 2A, and accordingly, only the scanner 140 is described below in the embodiment of FIG. 2B.

The scanner 140 according to one embodiment may perform electron beam (e-beam) scanning on the reference combination portion 110 and the comparison combination portion 120. The scanner 140 according to one embodiment may determine whether at least one of the first pads is aligned with at least one of the second pads based on the amount of electrons reflected from the reference combination portion 110 and the comparison combination portion 120 as a result of the electron beam scanning. For example, the scanner 140 may determine whether at least one of the first pads and at least one of the second pads are aligned or misaligned with each other based on colors derived from the reference combination portion 110 and the comparison combination portion 120 as a result of the electron beam scanning.

For example, the scanner 140 emits an electron beam to the reference combination portion 110 and the comparison combination portion 120 and determines whether the first pads are aligned with the second pads, the degree of alignment of the first pads and the second pads, and an alignment tendency based on the brightness according to the amount of reflected electrons. According to one embodiment, when the first reference pad 111 and the second reference pad 121 of the reference combination portion 110 are aligned with each other, the amount of reflected electrons is equal to the amount of emitted electrons, and accordingly, a scanning result of the reference combination portion 110 may display the brightness with a low gray level (e.g., relatively bright). However, when the first pad 121 and the second pad 122 of the comparison combination portion 120 are not aligned with each other, some of the emitted electrons are lost and the amount of reflected electrons may be less than the amount of emitted electrons. When the amount of reflected electrons is less than the amount of emitted electrons, the scanning result of the comparison combination portion 120 may display the brightness with a high gray level (e.g., relatively dark). As a result of the scanning, the reference combination portion 110 according to one embodiment may be displayed to be relatively bright, and a portion of the comparison combination portion 120 in which there is misalignment may be displayed dark.

The scanner 140 according to one embodiment may determine an alignment tendency and the degree of misalignment of the first pads and the second pads based on the scanning result. For example, when there are many bright parts as the scanning result, the scanner 140 may determine that the plurality of first pads are aligned with the second pads. However, when there are many dark parts as the scanning result, the scanner 140 may determine that there are many misaligned combination portions among the combination portions of the plurality of first pads and the plurality of second pads.

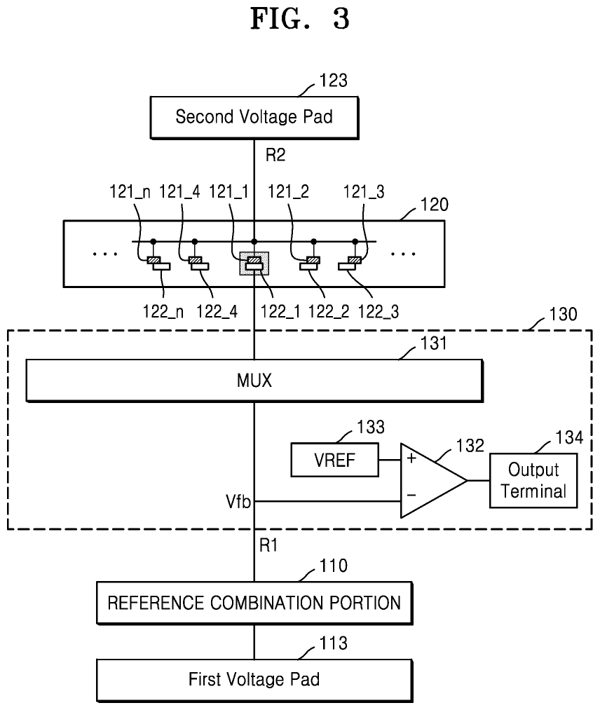

FIG. 3 is a block diagram illustrating the test circuit 130 according to one embodiment.

Referring to FIG. 3, the test circuit 130 according to one embodiment may include a multiplexer (MUX) 131, a comparator 132, a reference voltage pad 133, and an output terminal 134. The reference combination portion 110 according to one embodiment may be connected to a first voltage pad 113 to receive a first voltage and may have a reference resistance value R1. The comparison combination portion 120 according to one embodiment may be connected to a second voltage pad 123 to receive a second voltage and may have a comparison resistance value R2.

According to one embodiment, the test circuit 130 may be connected to the reference combination portion 110 and the comparison combination portion 120 through the multiplexer 131. The comparison combination portion 120 according to one embodiment may include a plurality of first pads 121_1, 121_2, 121_3, 121_4, . . . , 121_n and a plurality of second pads 122_1, 122_2, 122_3, 122_4, . . . , 122_n, and the plurality of first pads 121_1, 121_2, 121_3, 121_4, . . . , 121_n, may be respectively connected to the plurality of second pads 122_1, 122_2, 122_3, 122_4, . . . , 122_n. The test circuit 130 according to one embodiment may independently determine whether combinations of the plurality of first pads and the plurality of second pads are aligned. The test circuit 130 compares a voltage Vfb according to the distribution of the first voltage and the second voltage with a reference voltage VREF, and when it is determined that the voltage Vfb according to the distribution of the first voltage and the second voltage is equal to the reference voltage VREF, the test circuit 130 may determine that the plurality of first pads are aligned with the plurality of second pads.

The test circuit 130 according to one embodiment may compare the voltage Vfb according to the distribution of the first voltage and the second voltage with the reference voltage VREF and adjust the reference voltage VREF according to the comparison result. For example, the test circuit 130 may adjust the reference voltage VREF based on an output voltage of the comparator 132.

When the output voltage of the comparator 132 according to one embodiment is different from the preset answer sheet, the semiconductor multi-layer structure 100 may input the reference voltage VREF higher than the first voltage and the second voltage to the comparator 132 such that the output voltage of the comparator 132 is at a logic high level, and then, reduce the reference voltage VREF. For example, when the reference voltage VREF is higher than the voltage Vfb according to the distribution of the first voltage and the second voltage, the test circuit 130 may reduce the reference voltage. While the reference voltage VREF is reduced, the voltage Vfb according to the distribution of the first voltage and the second voltage may be equal to the reference voltage VREF at a certain point in time. The test circuit 130 according to one embodiment may determine the degree of alignment and an alignment tendency of the plurality of first pads and the plurality of second pads based on the amount of change in the reference voltage VREF. For example, until the voltage Vfb according to the distribution of the first voltage and the second voltage is equal to the reference voltage VREF, the degree of alignment and the alignment tendency of the plurality of first pads and the plurality of second pads may be determined based on the change in the reference voltage VREF, and when the change increases, the test circuit 130 may determine that the misalignment rate of the plurality of first pads and the plurality of second pads is increased.

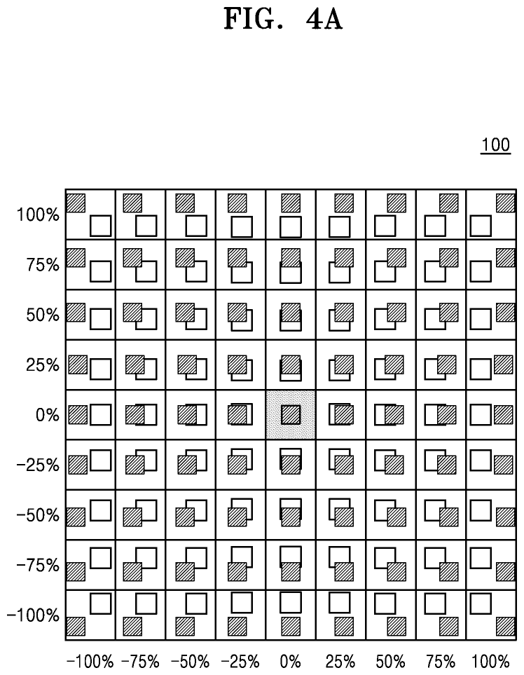

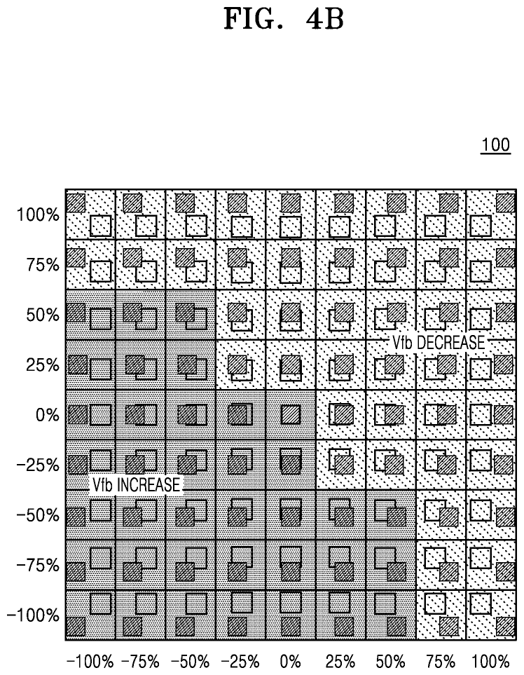

FIGS. 4A and 4B are diagrams illustrating a process of determining whether the semiconductor multi-layer structure 100 according to one embodiment is aligned.

FIG. 4A illustrates a preset answer sheet for determining whether the semiconductor multi-layer structure 100 according to one embodiment is aligned. Referring to FIG. 4A, the reference combination portion 110 according to one embodiment may have misalignment of 0%. The preset answer sheet according to one embodiment may include comparison combination portions with a high misalignment rate towards edges of the semiconductor multi-layer structure 100. The semiconductor multi-layer structure 100 according to one embodiment may include a first wafer including a plurality of first pads 121_1, 121_2, 121_3, 121_4, . . . , 121_n and a second wafer including a plurality of second pads 122_1, 122_2, 122_3, 122_4, . . . , 122_n. The semiconductor multi-layer structure 100 according to one embodiment may compare the preset answer sheet with an output of the test circuit 130 disclosed with respect to FIGS. 1 and 3 to determine alignment or misalignment and an alignment tendency of the plurality of first pads 121_1, 121_2, 121_3, 121_4, . . . , 121_n and the plurality of second pads 122_1, 122_2, 122_3, 122_4, . . . , 122_n.

Referring to FIG. 4B, when performing a test operation on the semiconductor multi-layer structure 100 according to one embodiment, there is a region where the voltage Vfb according to the distribution of the first voltage and the second voltage of FIG. 3 increases and a region where the voltage Vfb according to the distribution of the first voltage and the second voltage decreases. In the semiconductor multi-layer structure 100 according to one embodiment, the region where the voltage Vfb according to the distribution of the first voltage and the second voltage decreases may be determined to have a high misalignment combination ratio.

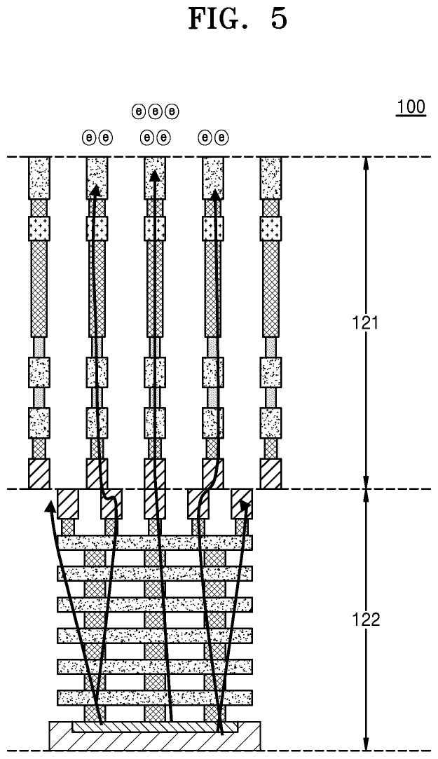

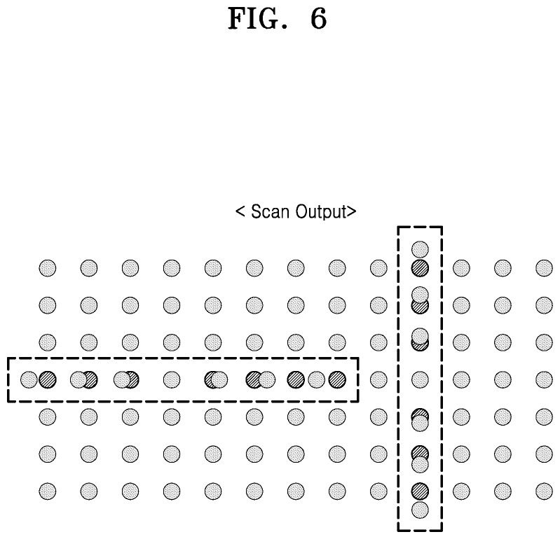

FIGS. 5 and 6 illustrate a process of determining alignment of the semiconductor multi-layer structure 100 by using a scanner, according to one embodiment.

Referring to FIGS. 3, 5, and 6, the amount of reflected electrons at the time when the plurality of first pads 121 and the plurality of second pads 122 according to one embodiment are aligned with each other may be greater than the amount of reflected electrons at the time when the plurality of first pads 121 and the plurality of second pads 122 are misaligned with each other. According to one embodiment, when the plurality of first pads 121 are not aligned with the plurality of second pads 122, some of the emitted electrons are lost and the amount of reflected electrons may be less than the amount of emitted electrons. When the amount of reflected electrons is less than the amount of emitted electrons, the brightness with a high gray level may be displayed as a scanning result. The scanner 140 according to one embodiment may determine an alignment tendency and the degree of misalignment of the plurality of first pads 121 and the plurality of second pads 122 based on the scanning result. For example, when there are many bright parts as the scanning result, the scanner 140 may determine that the plurality of first pads 121 are aligned with the plurality of second pads 122. In contrast to this, when there are many dark parts as the scanning result, the scanner 140 may determine that there are many misaligned combination portions among the combination portions of the plurality of first pads 121 and the plurality of second pads 122.

Referring to FIG. 6, the scanning result (scan output) according to one embodiment may be derived such that a misaligned portion may be visually detected. For example, parts including misaligned combination portions may be darker than parts including aligned combination portions. Also, the misaligned combination portions may be larger in size than the aligned combination portions because electrons are irregularly reflected from the misaligned combination portions.

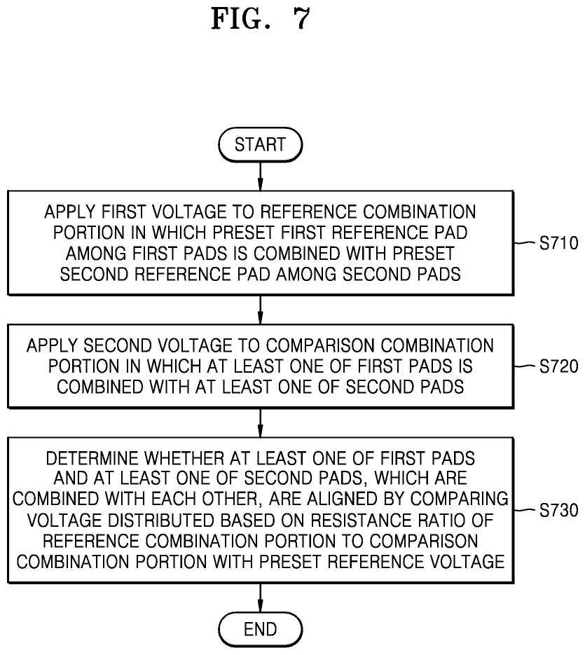

FIG. 7 is a flowchart illustrating an operating method of a test circuit, according to one embodiment.

Referring to FIGS. 2 and 7, the test circuit 130 according to one embodiment may apply a first voltage to the reference combination portion 110 in which the first reference pad 111 that is preset among the plurality of first pads is combined with the second reference pad 121 that is preset among the plurality of second pads (S710).

The first reference pad 111 and the second reference pad 121 of the reference combination portion 110 according to one embodiment may be aligned with each other 100%. A preset voltage may be applied to the reference combination portion 110 according to one embodiment, and the reference combination portion 110 may have the reference resistance value R1. In one embodiment, the voltage applied to the reference combination portion 110 may be a first voltage. Also, the first voltage may be an external voltage applied from the outside of the semiconductor multi-layer structure 100 or may be an internal voltage applied from the inside of the semiconductor multi-layer structure 100.

When the first voltage is applied to the test circuit 130, the test circuit 130 may apply a second voltage to the comparison combination portion 120 in which at least one first pad is combined with at least one second pad (S720).

The comparison combination portion 120 according to one embodiment may be a combination portion of the first pad 121 randomly selected from a plurality of first pads and the second pad 122 randomly selected from a plurality of second pads. A preset voltage is applied to the comparison combination portion 120 according to one embodiment, and the comparison combination portion 120 may have the comparison resistance value R2. In one embodiment, the voltage applied to the comparison combination portion 120 may be a second voltage. Also, the second voltage may be an external voltage applied from the outside of the semiconductor multi-layer structure 100 or may be an internal voltage applied from the inside of the semiconductor multi-layer structure 100.

When the first voltage and the second voltage are applied to the test circuit 130, the test circuit 130 may compare a voltage distributed based on a resistance ratio of the reference combination portion 110 to the comparison combination portion 120 with a preset reference voltage to determine whether at least one first pad and at least one second pad, which are combined with each other, are aligned with each other (S730).

Also, the test circuit 130 may determine the degree of misalignment of the first pad 121 and the second pad 122 of the comparison combination portion 120. According to one embodiment, the test circuit 130 may compare a voltage according to the distribution of the first voltage applied to the reference combination portion 110 and the second voltage applied to the comparison combination portion 120 with a preset reference voltage and compare the distributed voltage with the preset answer sheet, thereby determining the degree of alignment of the first pad 121 and the second pad 122. For example, the test circuit 130 may compare the voltage according to the distribution of the first voltage and the second voltage with the reference voltage of the preset answer sheet, and when misalignment is found, the test circuit 130 may check a change in the voltage according to the distribution of the first voltage and the second voltage through a change in the reference voltage and compare the voltage with the preset answer sheet, thereby determining the degree of alignment of the first pad 121 and the second pad 122. Also, the test circuit 130 may determine an alignment tendency of the first pad 121 and the second pad 122 of the comparison combination portion 120.

According to one embodiment, the test circuit 130 may repeat a process of comparing the voltage according to the distribution of the first voltage applied to the reference combination portion 110 and the second voltage applied to the comparison combination portion 120 with the preset reference voltage and determining the degree of alignment of the first pad 121 and the second pad 122. For example, the test circuit 130 may determine whether a plurality of pads are aligned with each other and the degree of alignment of the plurality of pads by comparing the voltage according to the distribution of the first voltage applied to the reference combination portion 110 and the second voltage applied to the comparison combination portion 120 with the preset reference voltage for the comparison combination portion 120 including at least one of the plurality of first pads and at least one of the plurality of second pads.

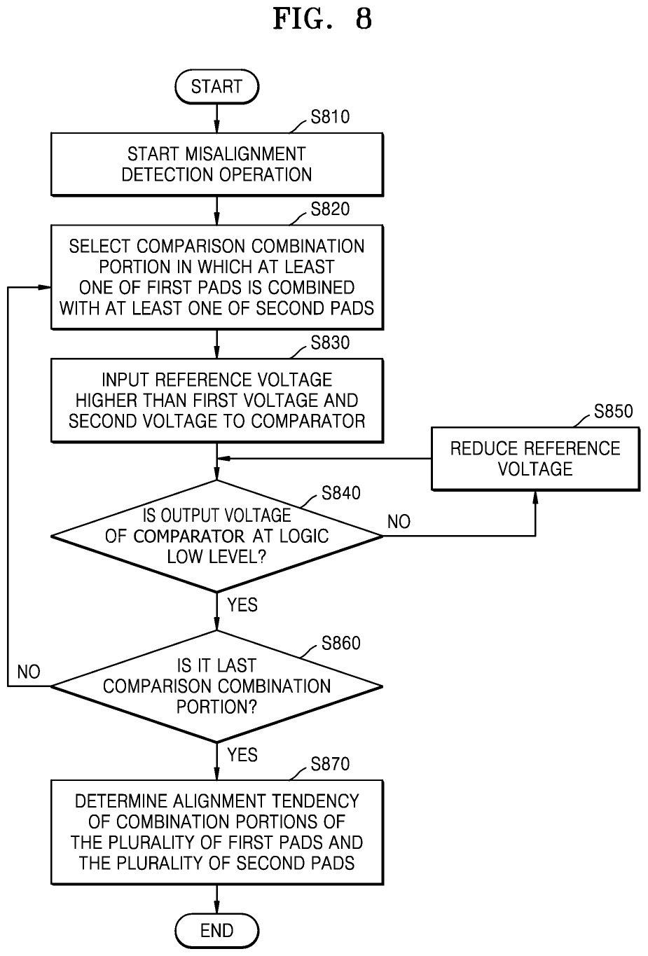

FIG. 8 is a flowchart illustrating a method of determining an alignment tendency of a first pad and a second pad in the operating method of the test circuit, according to one embodiment.

Referring to FIGS. 3 and 8, the test circuit 130 according to one embodiment may start a misalignment detection operation (S810).

When the misalignment detection operation starts, the test circuit 130 according to one embodiment may select a comparison combination portion 120 in which at least one first pad is combined with at least one second pad (S820). The selection of the comparison combination portion 120 according to one embodiment may be made randomly or may be made by a user.

When the comparison combination portion is selected, the test circuit 130 according to one embodiment may input the reference voltage VREF higher than the first voltage and the second voltage to the comparator 132 (S830). The test circuit 130 according to one embodiment may compare the voltage Vfb according to the distribution of the first voltage and the second voltage with the reference voltage VREF and may adjust the reference voltage VREF according to a comparison result. For example, the test circuit 130 may adjust the reference voltage VREF based on an output voltage of the comparator 132.

When the reference voltage VREF is input to the test circuit 130, the test circuit 130 may determine whether the output voltage of the comparator 132 is at a logic low level (S840).

When it is determined that the output voltage of the comparator 132 is not at a logic low level, the test circuit 130 according to one embodiment may reduce the reference voltage VREF (S850). When the output voltage of the comparator 132 according to one embodiment is at a logic high level, the semiconductor multi-layer structure 100 may reduce the reference voltage VREF. For example, when the reference voltage VREF is higher than the voltage Vfb according to the distribution of the first voltage and the second voltage, the test circuit 130 may reduce the reference voltage. While the reference voltage VREF is reduced, the voltage Vfb according to the distribution of the first voltage and the second voltage may be equal to the reference voltage VREF at a certain point in time. The test circuit 130 according to one embodiment may determine the degree of alignment of the plurality of first pads and the plurality of second pads based on the amount of change in the reference voltage VREF. For example, until the voltage Vfb according to the distribution of the first voltage and the second voltage is equal to the reference voltage VREF, the degree of alignment of the plurality of first pads and the plurality of second pads may be determined based on the change in the reference voltage VREF, and when the change increases, the test circuit 130 may determine that the misalignment rate of the plurality of first pads and the plurality of second pads is increased.

However, when it is determined that the output voltage of the comparator is at a logic low level, the test circuit 130 according to one embodiment may determine whether the comparison combination portion 120 of a test target is the last comparison combination portion (S860). The test circuit 130 according to one embodiment may repeat the determination of alignment of each of the combination portions of the plurality of first pads and the plurality of second pads until the determination of the last comparison combination portion is made.

When it is determined that the comparison combination portion 120 of a test target is the last comparison combination portion, the test circuit 130 according to one embodiment may determine an alignment tendency of the combination portions of the plurality of first pads and the plurality of second pads (S870). According to one embodiment, at a point in time when an output voltage of the comparator 132 changes from a logic high level to a logic low level, the test circuit 130 may determine an alignment tendency of the plurality of first pads and the plurality of second pads. For example, when each reference voltage VREF changed in all comparison combination portions 120 is less than the voltage Vfb according to the distribution of the first voltage and the second voltage, it is determined that the distribution voltages of all comparison combination portions 120 may be changed, and the test circuit 130 may determine an alignment tendency of the combination portions of the plurality of first pads and the plurality of second pads.

However, when it is determined that the comparison combination portion 120 of a test target is not the last comparison combination portion, the test circuit 130 according to one embodiment may select the comparison combination portion of at least one first pad and at least one second pad again and determine whether the plurality of first pads are aligned with the plurality of second pads in all regions on the semiconductor multi-layer structure 100.

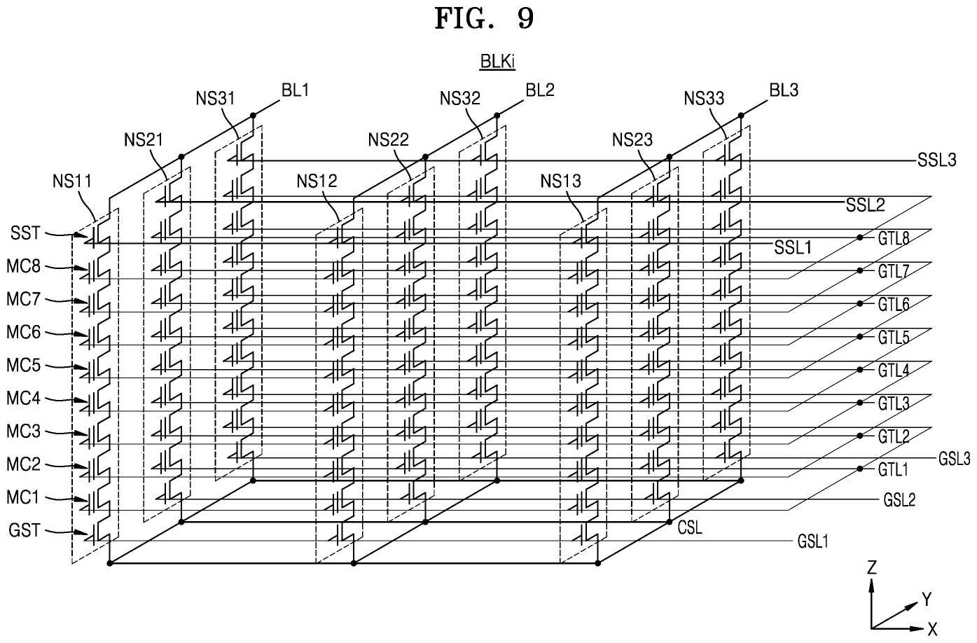

FIGS. 9 to 11 are diagrams illustrating a three-dimensional V-NAND structure that may be applied to a memory device included in a semiconductor wafer, according to one embodiment.

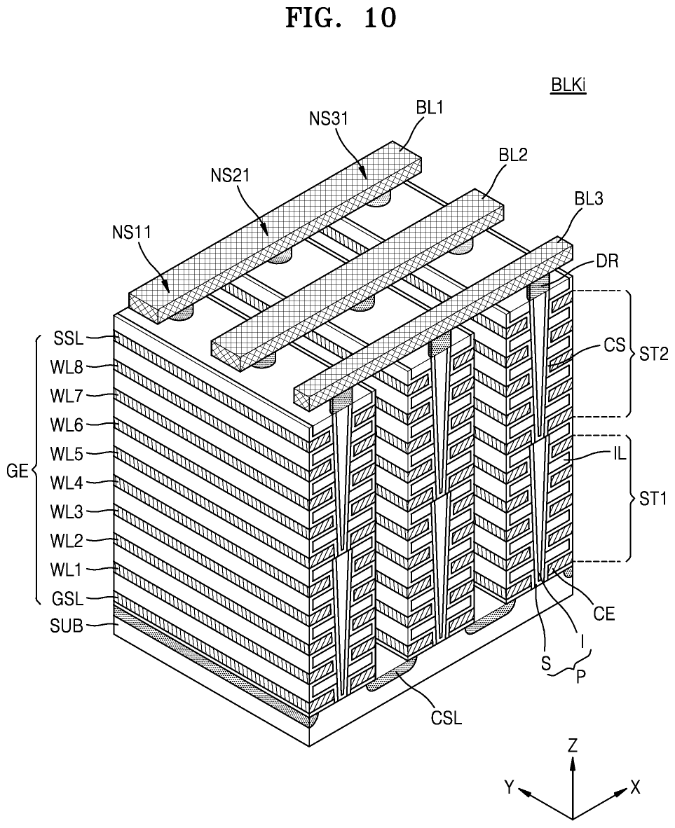

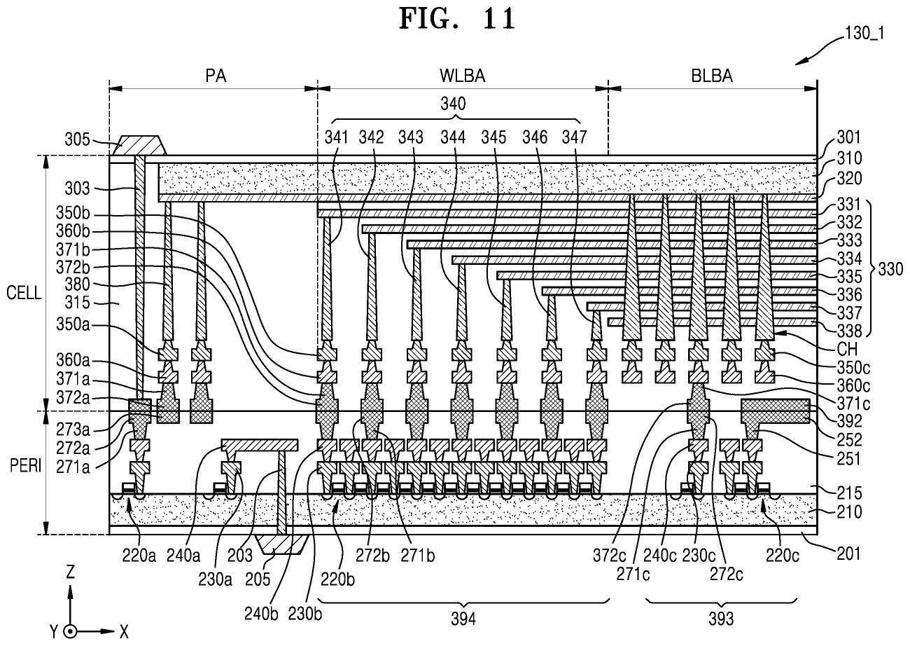

A nonvolatile memory applicable to a memory device included in the semiconductor multi-layer structure 100 according to the embodiment of FIG. 1 may include a plurality of memory blocks. FIGS. 9 and 10 illustrate a structure of one memory block BLKi among a plurality of memory blocks, and FIG. 11 illustrates an implementation example of a nonvolatile memory.

Referring to FIG. 9, the memory block BLKi may include a plurality of memory NAND strings NS11 to NS33 connected between bit lines BL1, BL2, and BL3 and a common source line CSL. Each of the plurality of memory NAND strings NS11 to NS33 may include a string select transistor SST, a plurality of memory cells MC1 to MC8, and a ground select transistor GST. For the sake of brevity of drawings, FIG. 10 illustrates that each of the plurality of memory NAND strings NS11 to NS33 includes eight memory cells MC1 to MC8 but is not limited thereto.

The string select transistor SST may be connected to a corresponding string select line among a plurality of string select lines SSL1, SSL2, and SSL3. The plurality of memory cells MC1 to MC8 may be respectively connected to a plurality of gate lines GTL1 to GTL8. The plurality of gate lines GTL1 to GTL8 may correspond to a plurality of word lines, and some of the plurality of gate lines GTL1 to GTL8 may correspond to dummy word lines. The ground select transistor GST may be connected to a corresponding ground select line among a plurality of ground select lines GSL1, GSL2, and GSL3. The string select transistor SST may be connected to a corresponding bit line among the bit lines BL1, BL2, and BL3, and the ground select transistor GST may be connected to the common source line CSL.

Gate lines (for example, GTL1) of the same height may be connected to each other, and the plurality of ground selection lines GSL1, GSL2, and GSL3 may be selected from the plurality of string selection lines SSL1, SSL2, and SSL3. Although FIG. 9 illustrates that the memory block BLKi is connected to eight gate lines GTL1 to GTL8 and three bit lines BL1, BL2, and BL3, the inventive concept is not limited thereto.

Referring to FIG. 10, the memory block BLKi is formed in a vertical direction with respect to a substrate SUB. Memory cells constituting each of the memory NAND strings NS11 to NS33 are formed by being stacked in a plurality of semiconductor layers.

The common source line CSL extending in a first direction (the Y direction) is on the substrate SUB. A plurality of insulating layers IL extending in the first direction (the Y direction) are sequentially provided in a third direction (the Z direction) in a region between two adjacent common source lines CSL on the substrate SUB and may be separated from each other by a certain distance in the third direction (the Z direction). A plurality of pillars P may be sequentially arranged in the first direction (the Y direction) in a region between two adjacent common source lines CSL on the substrate SUB, and pass through the plurality of insulating layers IL. The plurality of pillars P may pass through the plurality of insulating layers IL to be in contact with the substrate SUB. A surface layer S of each of the plurality of pillars P may include a silicon material doped with a first conductivity-type impurity and may function as a channel region.

An inner layer I of each of the plurality of pillars P may include an insulating material, such as silicon oxide, or an air gap. In a region between two adjacent common source lines CSL, a charge storage layer CS may be provided along the plurality of insulating layers IL, the plurality of pillars P, and an exposed surface of the substrate SUB. The charge storage layer CS may include a gate insulating layer (also referred to as a “tunneling insulating layer”), a charge trap layer, and a blocking insulating layer. Also, in the region between two adjacent common source lines CSL, gate electrodes GE, such as select lines GSL and SSL and a plurality of word lines WL1 to WL8, may be provided on an exposed surface of the charge storage layer CS. Drains or drain contacts DR may be respectively on the plurality of pillars P. The bit lines BL1 to BL3 extending in a second direction (the X direction) and separated from each other by a certain distance in the first direction (the Y direction) may be respectively on the drain contacts DR.

As illustrated in FIG. 10, each of the plurality of memory NAND string NS11 to NS33 may also have a structure in which a first memory stack ST1 and a second memory stack ST2 are stacked. The first memory stack ST1 may be connected to the common source line CSL, the second memory stack ST2 may be connected to the bit lines BL1 to BL3, and the first memory stack ST1 and the second memory stack ST2 are stacked to share channel holes with each other.

Referring to FIG. 11, a nonvolatile memory 130_1 may have a chip-to-chip (C2C) structure. In the C2C structure, an upper chip including a cell region CELL may be on a first wafer, a lower chip including a peripheral circuit region PERI may be on a second wafer that is different from the first wafer, and the upper chip may be connected to the lower chip by bonding. For example, the bonding may refer to electrically connecting a bonding metal formed on an uppermost metal layer of the upper chip to a bonding metal formed on an uppermost metal layer of the lower chip. For example, when the bonding metal is copper (Cu), the bonding may be Cu—Cu bonding, and the bonding metal may also include aluminum (Al) or tungsten (W).

Each of the peripheral circuit region PERI and the cell region CELL of the nonvolatile memory 130_1 may include an external pad bonding region PA, a word line bonding region WLBA, and a bit line bonding region BLBA.

The peripheral circuit region PERI may include a first substrate 210, an interlayer insulating layer 215, a plurality of circuit elements 220a, 220b, and 220c formed on the first substrate 210, first metal layers 230a, 230b, and 230c respectively connected to the plurality of circuit elements 220a, 220b, and 220c, and second metal layers 240a, 240b, and 240c respectively formed on the first metal layers 230a, 230b, and 230c. In one embodiment, the first metal layers 230a, 230b, and 230c may be formed of tungsten with relatively high electrical resistivity, and the second metal layers 240a, 240b, and 240c may be formed of copper with relatively low electrical resistivity.

Although only the first metal layers 230a, 230b, and 230c and the second metal layers 240a, 240b, and 240c are illustrated and described, the inventive concept is not limited thereto, and at least one metal layer may be further formed on the second metal layers 240a, 240b, and 240c. At least some of the one or more metal layers formed on the second metal layers 240a, 240b, and 240c may be formed of aluminum or so on with lower electrical resistivity than copper forming the second metal layers 240a, 240b, and 240c.

The interlayer insulating layer 215 may be on the first substrate 210 to cover the plurality of circuit elements 220a, 220b, 220c, the first metal layers 230a, 230b, and 230c, and the second metal layers 240a, 240b, and 240c and may include an insulating material, such as silicon oxide, silicon nitride, or so on.

Lower bonding metals 271b and 272b may be formed on the second metal layer 240b of the word line bonding region WLBA. In the word line bonding region WLBA, the lower bonding metals 271b and 272b of the peripheral circuit region PERI may be electrically connected to upper bonding metals 371b and 372b of the cell region CELL by a bonding method, and the lower bonding metals 271b and 272b and the upper bonding metals 371b and 372b may each be formed of aluminum, copper, or tungsten.

The cell region CELL may provide at least one memory block. The cell region CELL may include a second substrate 310 and a common source line 320. A plurality of word lines 331 to 338 (or 330) may be stacked on the second substrate 310 in a direction (a Z-axis direction) perpendicular to an upper surface of the second substrate 310. String select lines and a ground select line may be respectively arranged above and below the word lines 330, and the plurality of word lines 330 may be between the string select lines and the ground select line.

In the bit line bonding region BLBA, a channel structure CH may extend in a direction (the Z-axis direction) perpendicular to the upper surface of the second substrate 310 to pass through the plurality of word lines 330, the string select lines, and the ground select line. The channel structure CH may include a data storage layer, a channel layer, and a buried insulating layer, and the channel layer may be electrically connected to a first metal layer 350c and a second metal layer 360c. For example, the first metal layer 350c may be a bit line contact, and the second metal layer 360c may be referred to as a bit line 360c. In one embodiment, the bit line 360c may extend in a first direction (a Y-axis direction) parallel to the upper surface of the second substrate 310.

A region where the channel structure CH and the bit line 360c are arranged may be defined as the bit line bonding region BLBA. In the bit line bonding region BLBA and the peripheral circuit region PERI, the bit line 360c may be electrically connected to the circuit elements 220c included in a page buffer 393. For example, the bit line 360c may be connected to the upper bonding metals 371c and 372c, and the upper bonding metals 371c and 372c may be connected to the lower bonding metals 271c and 272c connected to the circuit elements 220c of the page buffer 393 in the peripheral circuit region PERI.

In the word line bonding region WLBA, the plurality of word lines 330 may extend in a second direction (an X-axis direction) perpendicular to the first direction and parallel to the upper surface of the second substrate 310, and may be connected to a plurality of cell contact plugs 341 to 347 (or 340). The plurality of word lines 330 may be respectively connected to the plurality of cell contact plugs 340 respectively through pads which are respectively formed by extending in the second direction at least some of the plurality of word lines 330 in different lengths. A first metal layer 350b and a second metal layer 360b may be sequentially connected to an upper portion of each of the plurality of cell contact plugs 340 respectively connected to the plurality of word lines 330. The plurality of cell contact plugs 340 in the word line bonding region WLBA may be connected through the upper bonding metals 371b and 372b in the cell region CELL to the lower bonding metals 271b and 272b in the peripheral circuit region PERI.

The plurality of cell contact plugs 340 may be electrically connected to the circuit elements 220b included in a row decoder 394 in the peripheral circuit region PERI. In one embodiment, operating voltages of the circuit elements 220b included in the row decoder 394 may be different from operating voltages of the circuit elements 220c included in the page buffer 393. For example, the operating voltages of the circuit elements 220c included in the page buffer 393 may be greater than the operating voltages of the circuit elements 220b included in the row decoder 394.

A common source line contact plug 380 may be in the external pad bonding region PA. The common source line contact plug 380 may be formed of a conductive material, such as metal, metal compound, or polysilicon, and may be electrically connected to the common source line 320. A first metal layer 350a and a second metal layer 360a may be sequentially stacked on the common source line contact plug 380. For example, a region where the common source line contact plug 380, the first metal layer 350a, and the second metal layer 360a are arranged may be defined as the external pad bonding region PA.

In addition, first input/output pad 205 and second input/output pad 305 may be in the external pad bonding region PA. A lower insulating layer 201 covering a lower surface of the first substrate 210 may be formed on a lower portion of the first substrate 210, and the first input/output pad 205 may be formed on the lower insulating layer 201. The first input/output pad 205 may be connected through the first input/output contact plug 203 to at least one of the plurality of circuit elements 220a, 220b, and 220c in the peripheral circuit region PERI, and may be separated from the first substrate 210 by the lower insulating layer 201. Also, a side insulating layer may be between the first input/output contact plug 203 and the first substrate 210 to electrically separate the first input/output contact plug 203 from the first substrate 210.

An upper insulating layer 301 covering an upper surface of the second substrate 310 may be formed on the second substrate 310, and the second input/output pad 305 may be on the upper insulating layer 301. The second input/output pad 305 may be connected through the second input/output contact plug 303 to at least one of the plurality of circuit elements 220a, 220b, and 220c in the peripheral circuit region PERI. In one embodiment, the second input/output pad 305 may be electrically connected to the circuit element 220a.

Depending on embodiments, the second substrate 310, the common source line 320, and so on may not be in a region where the second input/output contact plug 303 is arranged. Also, the second input/output pad 305 may not overlap the plurality of word lines 330 in the third direction (the Z-axis direction). The second input/output contact plug 303 may be separated from the second substrate 310 in a direction parallel to an upper surface of the second substrate 310 and may pass through an interlayer insulating layer 315 in the cell region CELL to be connected to the second input/output pad 305.

Depending on embodiments, the first input/output pad 205 and the second input/output pad 305 may be formed selectively. For example, the nonvolatile memory 130_1 may include only the first input/output pad 205 on an upper portion of the first substrate 210, or may include only the second input/output pad 305 on an upper portion of the second substrate 310. Alternatively, the nonvolatile memory 130_1 may include both the first input/output pad 205 and the second input/output pad 305.

A metal pattern of an uppermost metal layer may be formed as a dummy pattern or the uppermost metal layer may not be formed in each of the external pad bonding region PA and the bit line bonding region BLBA included in each of the cell region CELL and the peripheral circuit region PERI.

In the external pad bonding region PA of the nonvolatile memory 130_1, a lower metal pattern 273a having the same shape as an upper metal pattern 372a of the cell region CELL may be formed on an uppermost metal layer in the peripheral circuit region PERI to correspond to the upper metal pattern 372a formed on an uppermost metal layer in the cell region CELL. The lower metal pattern 273a formed on the uppermost metal layer in the peripheral circuit region PERI may not be connected to a separate contact in the peripheral circuit region PERI. Similarly, in the external pad bonding region PA, an upper metal pattern 373a having the same shape as the lower metal pattern 273a in the peripheral circuit region PERI may also be formed on an upper metal layer in the cell region CELL to correspond to the lower metal pattern 273a formed on the uppermost metal layer in the peripheral circuit region PERI.

The lower bonding metals 271b and 272b may be formed on the second metal layer 240b in the word line bonding region WLBA. In the word line bonding region WLBA, the lower bonding metals 271b and 272b in the peripheral circuit region PERI may be electrically connected to the upper bonding metals 371b and 372b in the cell region CELL by a bonding method.

Also, in the bit line bonding region BLBA, an upper metal pattern 392 having the same shape as a lower metal pattern 252 in the peripheral circuit region PERI may be formed on an uppermost metal layer in the cell region CELL to correspond to the lower metal pattern 252 formed on an uppermost metal layer in the peripheral circuit region PERI. A contact may not be formed on the upper metal pattern 392 formed on the uppermost metal layer in the cell region CELL.

According to the embodiments described above, when manufacturing one semiconductor device by combining two or more semiconductor dies or manufacturing a plurality of semiconductor devices by combining two or more semiconductor wafers, a device and method may accurately determine whether a plurality of semiconductor wafers are aligned with each other by including the configurations described above.

The semiconductor dies and semiconductor wafers according to the embodiments may support a test operation for determining accuracy of alignment. The semiconductor dies and semiconductor wafers may have pads used for a test operation. Alignment and combination of the semiconductor dies and semiconductor wafers according to embodiments may be easily and accurately checked by performing a test operation.

While aspects of the inventive concept have been particularly shown and described with reference to embodiments thereof, it will be understood that various changes in form and details may be made therein without departing from the spirit and scope of the following claims.

What is claimed is:

1. A semiconductor multi-layer structure comprising:
a first semiconductor wafer including a plurality of first pads;
a second semiconductor wafer including a plurality of second pads combined with the plurality of first pads; and
a test circuit configured to apply a first voltage to a reference combination portion in which a preset first reference pad among the plurality of first pads is combined with a preset second reference pad among the plurality of second pads and
apply a second voltage to a comparison combination portion in which at least one first pad among the plurality of first pads is combined with at least one second pad among the plurality of second pads,
wherein the test circuit compares a voltage distributed based on a resistance ratio of the reference combination portion to the comparison combination portion with a preset reference voltage to determine whether the at least one first pad is aligned with the at least one second pad.

2. The semiconductor multi-layer structure of claim 1, wherein the test circuit comprises a comparator that compares the voltage distributed based on the resistance ratio of the reference combination portion to the comparison combination portion with the preset reference voltage.

3. The semiconductor multi-layer structure of claim 1, wherein the test circuit determines a degree of misalignment of the at least one first pad and the at least one second pad combined with each other.

4. The semiconductor multi-layer structure of claim 1, wherein the test circuit compares the voltage distributed based on a resistance ratio of the reference combination portion to the comparison combination portion with the preset reference voltage and determines an alignment tendency of the plurality of first pads and the plurality of second pads based on a comparison result.

5. The semiconductor multi-layer structure of claim 1, wherein the plurality of first pads and the plurality of second pads are arranged to have a square matrix structure.

6. The semiconductor multi-layer structure of claim 2, wherein
the test circuit inputs the preset reference voltage higher than the first voltage and the second voltage to the comparator when misalignment is found, and
reduces the preset reference voltage when an output voltage of the comparator is at a logic high level.

7. The semiconductor multi-layer structure of claim 2, wherein
the test circuit inputs the preset reference voltage higher than the first voltage and the second voltage to the comparator when misalignment is checked, and
determines an alignment tendency of the plurality of first pads and the plurality of second pads at a point in time when an output voltage of the comparator changes from a logic high level to a logic low level.

8. The semiconductor multi-layer structure of claim 7, wherein the alignment tendency of the plurality of first pads and the plurality of second pads is determined based on a preset answer sheet.

9. The semiconductor multi-layer structure of claim 1, wherein
the test circuit comprises:
a first voltage pad configured to receive the first voltage;
a second voltage pad configured to receive the second voltage; and
a reference voltage pad configured to receive the preset reference voltage.

10. A semiconductor multi-layer structure comprising:
a first semiconductor wafer including a plurality of first pads;
a second semiconductor wafer including a plurality of second pads combined with the plurality of first pads; and
a scanner configured to perform electron beam scanning of a reference combination portion in which a preset first reference pad among the plurality of first pads is combined with a preset second reference pad among the plurality of second pads and a comparison combination portion in which at least one first pad among the plurality of first pads is combined with at least one second pad among the plurality of second pads,
wherein the scanner determines whether the at least one first pad is aligned with the at least one second pad based on an amount of electrons reflected from the reference combination portion and the comparison combination portion during the electron beam scanning.

11. The semiconductor multi-layer structure of claim 10, wherein the scanner determines whether the at least one first pad is combined with the at least one second pad based on colors derived from the reference combination portion and the comparison combination portion as a result of the electron beam scanning.

12. The semiconductor multi-layer structure of claim 10, wherein the scanner determines a degree of misalignment of the at least one first pad and the at least one second pad combined with each other.

13. The semiconductor multi-layer structure of claim 10, wherein the scanner determines an alignment tendency of the plurality of first pads and the plurality of second pads based on a result of the electron beam scanning.

14. The semiconductor multi-layer structure of claim 10, wherein the plurality of first pads and the plurality of second pads are arranged to have a square matrix structure.

15. An operating method of a test circuit for determining whether a semiconductor multi-layer structure including a three-dimensional memory device is aligned, the operating method comprising:
applying a first voltage to a reference combination portion in which a preset first reference pad among a plurality of first pads included in a first wafer is combined with a preset second reference pad among a plurality of second pads included in a second wafer;
applying a second voltage to a comparison combination portion in which at least one first pad among the plurality of first pads is combined with at least one second pad among the plurality of second pads; and
determining whether the at least one first pad is aligned with the at least one second pad by comparing a voltage distributed based on a resistance ratio of the reference combination portion to the comparison combination portion with a preset reference voltage.

16. The operating method of claim 15, wherein,
in the determining whether the at least one first pad is aligned with the at least one second pad,
a degree of misalignment of the at least one first pad and the at least one second pad combined with each other is determined.

17. The operating method of claim 15, wherein,
in the determining whether the at least one first pad is aligned with the at least one second pad,
an alignment tendency of the plurality of first pads and the plurality of second pads is determined.

18. The operating method of claim 15, wherein,
in the determining whether the at least one first pad is aligned with the at least one second pad,
an output voltage of a comparator included in the test circuit is determined, and
when the output voltage of the comparator is at a logic high level,
the preset reference voltage is reduced.

19. The operating method of claim 15, wherein
the determining whether the at least one first pad is aligned with the at least one second pad comprises:
determining an output voltage of a comparator included in the test circuit; and
inputting the preset reference voltage higher than the first voltage and the second voltage to the comparator when misalignment is checked, and determining an alignment tendency of the plurality of first pads and the plurality of second pads at a point in time when the output voltage of the comparator changes from a logic high level to a logic low level.

20. The operating method of claim 19, wherein
the determining of the alignment tendency of the plurality of first pads and the plurality of second pads comprises:
determining the alignment tendency of the plurality of first pads and the plurality of second pads based on a preset answer sheet.
